(19) United States
(12) Patent Application Publication
(10) Pub. No.: US 2015/0200368 A1
(43) Pub. Date: Jul. 16, 2015

(54) SEMICONDUCTOR INTEGRATED CIRCUIT DEVICE HAVING PHASE-CHANGE STRUCTURE AND METHOD OF MANUFACTURING THE SAME

(71) Applicant: SK hynix Inc., Gyeonggi-do (KR)

(72) Inventors: Seung Yun LEE, Gyeonggi-do (KR); Kang Sik CHOI, Gyeonggi-do (KR)

(73) Assignee: SK hynix Inc., Gyeonggi-do (KR)

(21) Appl. No.: 14/255,568

(22) Filed: Apr. 17, 2014

(30) Foreign Application Priority Data
Jan. 13, 2014 (KR) 10-2014-0003927

(51) Int. Cl. H01L 45/00

(52) U.S. Cl. CPC H01L 45/1691; H01L 45/06; H01L 45/1625; H01L 45/1675

(57) ABSTRACT

A semiconductor integrated circuit device including a phase-change structure and a method of manufacturing the same are provided. The method includes providing a semiconductor substrate including a lower electrode, sequentially stacking a plurality of phase-change material layers on the semiconductor substrate, and patterning the stacked plurality of phase-change material layers in a stepwise manner to form a phase-change structure.

### CROSS-REFERENCES TO RELATED APPLICATION

This application claims priority under 35 U.S.C. 119(a) to Korean application No. 10-2014-0003927, filed on Jan. 13, 2014, which is incorporated by reference in its entirety.

### BACKGROUND

1. Technical Field

Various embodiments of the inventive concept relate to a semiconductor integrated circuit device and a method of manufacturing the same, and more particularly, to a semiconductor integrated circuit device having a phase-change structure and a method of manufacturing the same.

2. Related Art

With the rapid development of mobile and digital information communication and the consumer-electronics industry, studies on existing electronic charge controlled-devices have revealed limitations. Thus, new functional memory devices having novel concepts other than those in existing electronic charge devices need to be developed. Particularly, next-generation memory devices with large capacities, ultra-high speed, and ultra-low power need to be developed to satisfy demands for large capacity memories of electronic information devices.

Resistive variable memory devices using a resistance material as a memory medium have been suggested as the next-generation memory devices, and typical examples of resistive variable memory devices may include phase-change random access memories (PCRAMs), resistance RAMS (RRAMs), or spin-torque transfer magnetoresistive RAMs.

A resistive variable memory device may be formed of a switching device and a resistance device and may store data values of “0” or “1,” according to the state of the resistance device.

Even in resistive variable memory devices, the first priority is to improve integration density by integrating as many memory cells as possible in a limited small area.

Currently, a PCRAM uses a phase-change material layer used as a resistance device in a confined method. The confined method is a method of forming a phase-change space in advance, and depositing the phase-change material layer in the confined phase-change space. The confined method is disclosed in U.S. patent publication No. 2013/099188.

The phase-change material layer is generally formed through a physical vapor deposition (PVD) method to control composition uniformity.

With an increase of integration density in PCRAM, the phase-change space has narrowed. Thus, it is difficult to deposit the phase-change material layer in the narrow phase-change space using the PVD method. As is known, the PVD method is advantageous in maintaining composition uniformity of a deposited material, but the PVD method has poor gap-filling characteristics.

Technology for depositing a phase-change material layer using atomic layer deposition (ALD) has been suggested. The ALD method has good gap-filling characteristics compared with the PVD method, but the ALD method is disadvantageous in terms of uniformity of the phase-change material layer and interface characteristics between the phase-change material layer and a lover electrode.

### SUMMARY

An exemplary embodiment provides method of manufacturing a semiconductor integrated circuit device. The method may include providing a semiconductor substrate including a lower electrode, sequentially stacking a plurality of phase-change material layers on the semiconductor substrate, and patterning the stacked plurality of phase-change material layers in a stepwise manner to form a phase-change structure.

In another exemplary embodiment, the method may include providing a semiconductor substrate having a lower electrode, sequentially stacking a plurality of phase-change material layers (each having a different material property) on the semiconductor substrate via physical vapor deposition (PVD), and patterning the stacked plurality of phase-change material layers based on the different material properties to form a phase-change structure.

These and other features, aspects, and embodiments are described below in the section entitled “DETAILED DESCRIPTION”.

### BRIEF DESCRIPTION OF THE DRAWINGS

The above and other aspects, features and advantages of the subject matter of the present disclosure will be more clearly understood from the following detailed description taken in conjunction with the accompanying drawings, in which:

FIGS. 1 to 5 are cross-sectional views illustrating a method of manufacturing a semiconductor integrated circuit device according to an exemplary embodiment of the inventive concept;

FIG. 6 is a cross-sectional view illustrating a semiconductor integrated circuit device according to an exemplary embodiment of the inventive concept;

FIGS. 7 to 14 are cross-sectional views illustrating a method of manufacturing a semiconductor integrated circuit device according to an exemplary embodiment of the inventive concept;

FIG. 15 is a perspective view illustrating a semiconductor integrated circuit device according to an exemplary embodiment of the inventive concept;

FIG. 16 is a block diagram illustrating a microprocessor according to an exemplary embodiment of the inventive concept;

FIG. 17 is a block diagram illustrating a processor according to an exemplary embodiment of the inventive concept; and

FIG. 18 is a block diagram illustrating a system according to an embodiment of the inventive concept.

### DETAILED DESCRIPTION

Exemplary embodiments will be described in greater detail with reference to the accompanying drawings. Exemplary embodiments are described herein with reference to cross-sectional schematic illustrations of exemplary embodiments (and intermediate structures). In reducing embodiments to practice, variations in shape and size are to be expected relative to the embodiments illustrated in the drawings. These variations may be normal for a given manufacturing method or may come from design changes within the scope and spirit of this invention. Thus, exemplary embodiments should not be construed as limiting the particular shapes of regions illustrated but may include deviations in shapes that result, for example, from manufacturing. In the drawings, lengths and sizes of layers and regions may be exaggerated for clarity. Throughout the disclosure, reference numerals correspond directly to the like numbered parts in the various figures and embodiments of the present invention. It should be understood that the meaning of “on” and “over” in the present disclosure should be interpreted in the broadest manner such that “on” means not only “directly on” but also “on” something with an intermediate feature(s) or a layer(s) therebetween, and that “over” means not only directly on top but also on top of something with an intermediate feature(s) or a layer(s) therebetween. It is also noted that in this specification, “connected/coupled” refers to one component not only directly coupling another component but also indirectly coupling another component through an intermediate component. In addition, the singular form may include the plural form as long as it is not specifically mentioned.

Embodiments of the inventive concept are described herein with reference to cross-section and/or plan illustrations. However, exemplary embodiments of the inventive concept should not be construed as limiting the inventive concept. It will be appreciated by those of ordinary skill in the art that changes may be made in these exemplary embodiments without departing from the principles and spirit of the inventive concept.

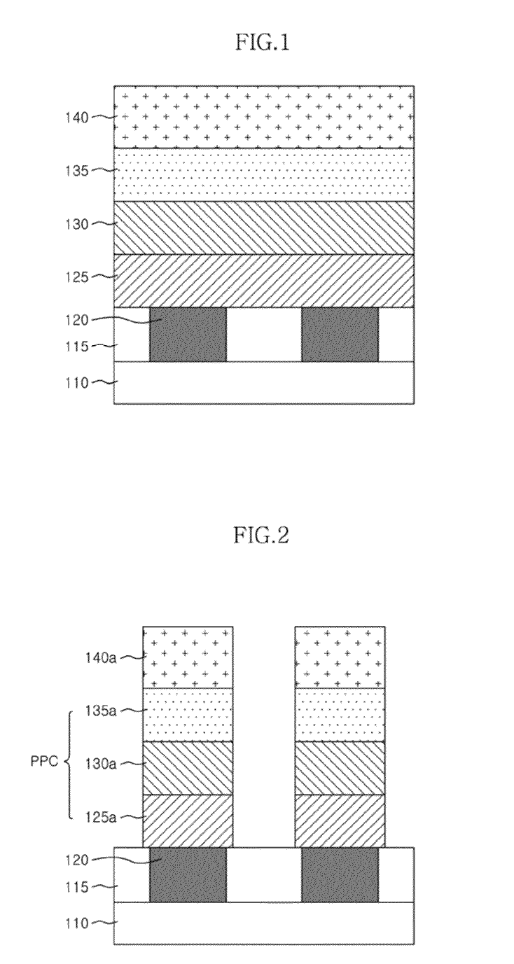

Referring to FIG. 1, an interlayer insulating layer 115 is formed on a semiconductor substrate 110. Although not shown in FIG. 1, a switching device may be formed between the semiconductor substrate 110 and the interlayer insulating layer 115 through a known method. A lower electrode region (not shown) may be formed by etching a predetermined portion of the interlayer insulating layer 115. A conductive material is filled in the lower electrode region to form a lower electrode 120. The formation of the lower electrode 120 may be formed through various methods.

A first phase-change material layer 125, a second phase-change material layer 130, and a third phase-change material layer 135, are sequentially deposited on the interlayer insulating layer 115, where the lower electrode 120 is formed. For example, the first phase-change material layer 125 may have the same etch rate as the second phase-change material layer 130 under a first etch condition, and the first phase-change material layer 125 may have an etch rate larger than the etch rate of the second phase-change material layer 130 under a second etch condition different from the first etch condition. The second phase-change material layer 130 may have an etch rate larger than the etch rate of the third phase-change material layer 135 under a specific etch condition. In other words, the first-change material layer 125, the second phase-change material layer 130, and a third phase-change material layer 135 may have a different etch selectivity according to an etch condition, for example, an etching solution or a temperature. The first etch condition may be an anisotropic dry etch condition, and the second etch condition may be a dry or wet etch condition. Further, the etch rate of the phase-change material layers may be controlled, for example, through change of a composition ratio thereof. The first to third phase-change material layers 125, 130, and 135 may be formed, for example, through a PVD method to maintain composition uniformity. The first to third phase-change material layers 125, 130, and 135 may have the same thickness or different thicknesses. An upper electrode layer 140 is deposited on the third phase-change material layer 135.

Referring to FIG. 2, the upper electrode layer 140, the third phase-change material layer 135, the second phase-change material layer 130, and the first phase-change material layer 125 are preliminarily etched to form an upper electrode 140a, and a preliminary phase-change structure PPC, which includes first to third phase-change patterns 125a, 130a, and 135a, each having the same width as the upper electrode 140a. The preliminary etching may be performed under the first etch conditions, for example, under the conditions where the first to third phase-change material layers 125, 130, and 135 are etched at the same etch rate.

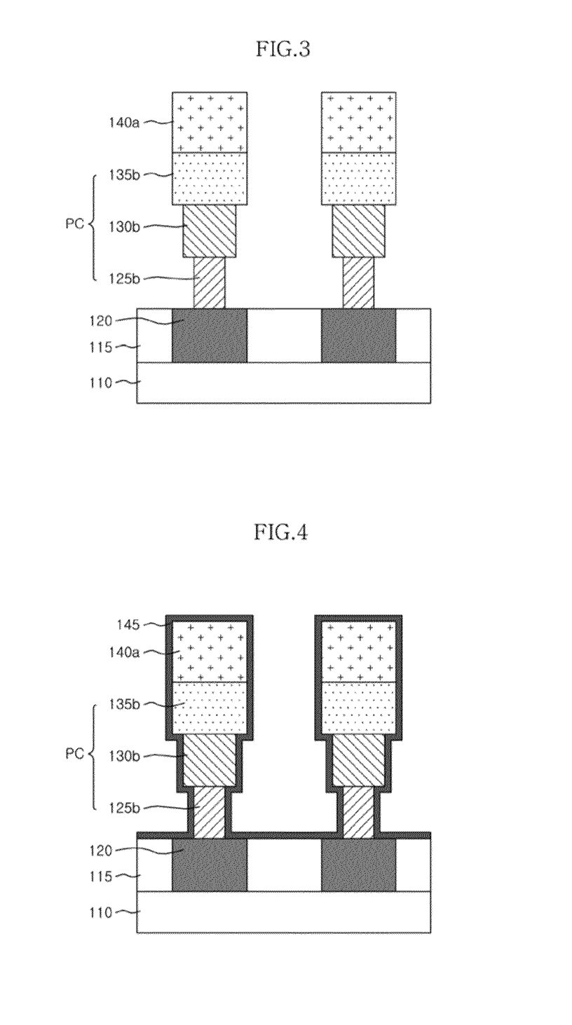

Referring to FIG. 3, the preliminary phase-change structure PPC is subjected to a main etching. The main etching may be performed under the second etch condition, for example, under the condition that the first and second phase-change patterns 125a and 130a are etched more than the third phase-change pattern 135a. Therefore, a phase-change structure PC having a line width reduced in a stepwise manner is formed. The reference numerals 125b, 130b, and 135b denote the first to third phase-change patterns that form the phase-change structure PC.

Referring to FIG. 4, a protection layer 145 is formed on a surface of the phase-change structure PC, a surface of the interlayer insulating layer 115, and a surface of the lower electrode 120. The protection layer 145 may include, for example, a silicon nitride layer or a silicon oxide layer. Alternatively, the protection layer 145 may include a metal oxide layer, a metal nitride layer, or a nitride layer to form a parallel resistor with the phase-change patterns. In some cases, the protection layer 145 may be partially removed to expose the interlayer insulating layer 115.

Referring to FIG. 5, the space between phase-change structures PC is filled with an insulating layer 150. At this time, an air void 155 may be formed in the insulating layer 150 due to the aspect ratio of the phase-change structure PC. Since the air void 150 has a high dielectric constant, the air void may serve as an air gap and act as an insulating layer. The air void 150 has low thermal conductivity and may also perform a function of a heat insulating layer. Subsequently, the insulating layer 150 is planarized to expose a surface of the upper electrode 140a.

In the above-described exemplary embodiment, the shape of the phase-change structure PC is constructed by depositing the phase-change material layers and patterning the phase-change material layers in a predetermined form. The phase-change material layer may be formed through a PVD method without burying the phase-change material layer. Accordingly, the composition uniformity of the phase-change material layer may be maintained.

The phase-change structure PC may be formed by stacking multi-layered phase-change material layers, each having a different etch selectivity, and patterning the phase-change material layers to have a step structure. Therefore, the filling of spaces between the phase-change structures with an insulating layer may be improved.

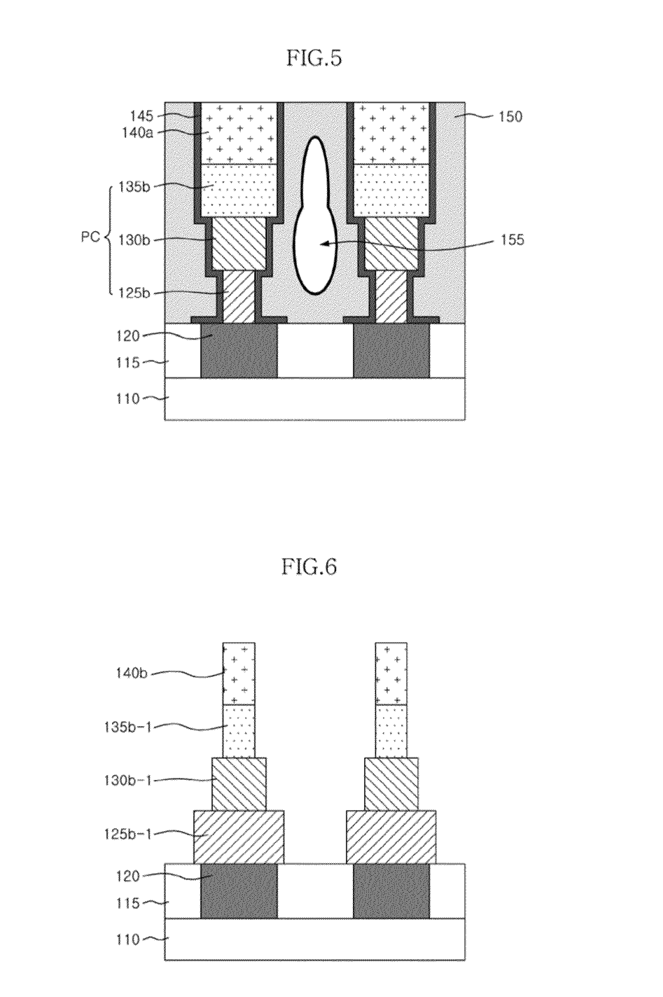

According to an exemplary embodiment, an etch selectivity of the phase-change structure PC may increase in a direction away from the substrate 110, from the first phase-change material layer 125 to the third phase-change material layer 135. However, as illustrated in FIG. 6, in an alternative embodiment, an etch selectivity of a phase-change structure may increase in a direction toward the substrate 110, from a third phase-change material layer 135 to a first phase-change material layer 125, so that a line width of a second phase-change pattern 130b-1 is smaller than a line width of a first phase-change material pattern 125b-1, and a line width of a third phase-change pattern 135b-1 is smaller than a line width of the second phase-change pattern 130b-1.

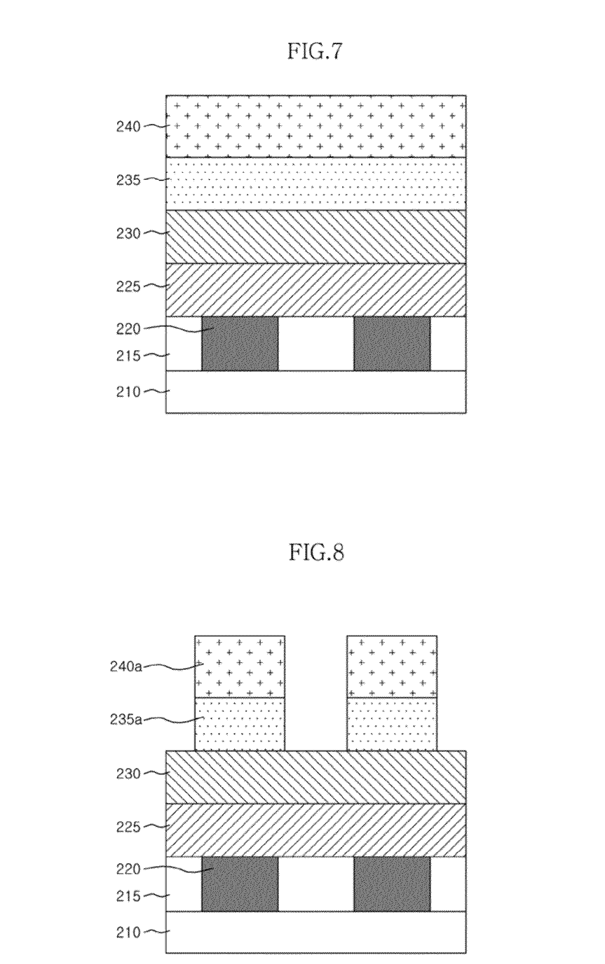

A method of manufacturing a semiconductor integrated circuit device according to an exemplary embodiment of the inventive concept will be described with reference to FIGS. 7 to 14.

Referring to FIG. 7, similar to the process described in FIG. 1, first to a third phase-change material layers 225, 230, and 235 having different etch selectivities are sequentially stacked on a semiconductor substrate 210, including a lower electrode 220, and an upper electrode layer 240 is formed on the third phase-change material layer 235. The first to third phase-change material layers 225, 230, and 235 may be stacked so that etching selectivities of the first to third phase-change material layers 225, 230, and 235 increase in a direction away from the substrate 210. The first to third phase-change material layers 225, 230, and 235 may be deposited through a PVD method to minimize changes in composition ratio. The reference numeral 215 denotes an interlayer insulating layer.

Referring to FIG. 8, the upper electrode layer 240 and the third phase-change material layer 235 are patterned to a preset size to form an upper electrode 240a and a third phase-change pattern 235a.

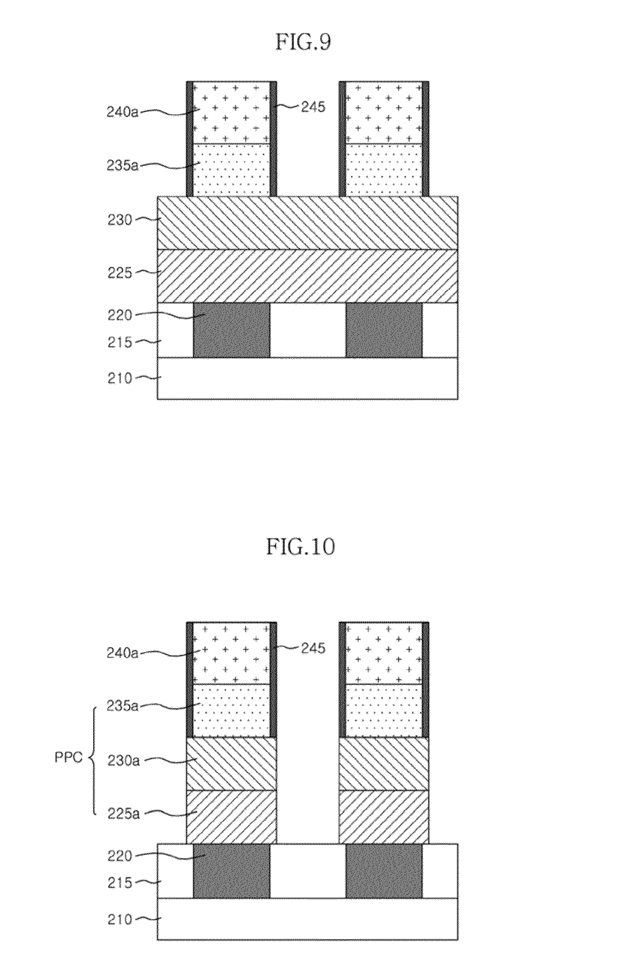

Referring to FIG. 9, a first protection layer 245 is formed on sidewalls of the upper electrode 240a and the third phase-change pattern 235a. The protection layer 245 may include, for example, a silicon nitride layer or a silicon oxide layer. The first protection layer 245 is not limited thereto and may include a metal oxide layer or a metal nitride layer to form a parallel resistor with the phase-change patterns. The first protection layer 245 may be deposited on the semiconductor substrate, the upper electrode 240a, and the third phase-change pattern 235a. Next, the first protection layer 245 may be anisotropically etched to expose surfaces of the upper electrode 240a and the second phase-change material layer 230, so that the first protection layer 245 is formed on the sidewalls of the upper electrode 240a and the third phase-change pattern 235a.

Referring to FIG. 10, the first and second phase-change material layers 225 and 230 are preliminarily etched to form a preliminary phase-change structure PPC, using the third phase-change pattern 235a and the upper electrode 240a covered with the first protection layer 245 as a mask pattern. The preliminary etching may be performed under the conditions where the first and second phase-change material layers 225 and 230 were etched at the same rate. The reference numeral 225a denotes a first phase-change pattern, and 230a denotes a second phase-change pattern.

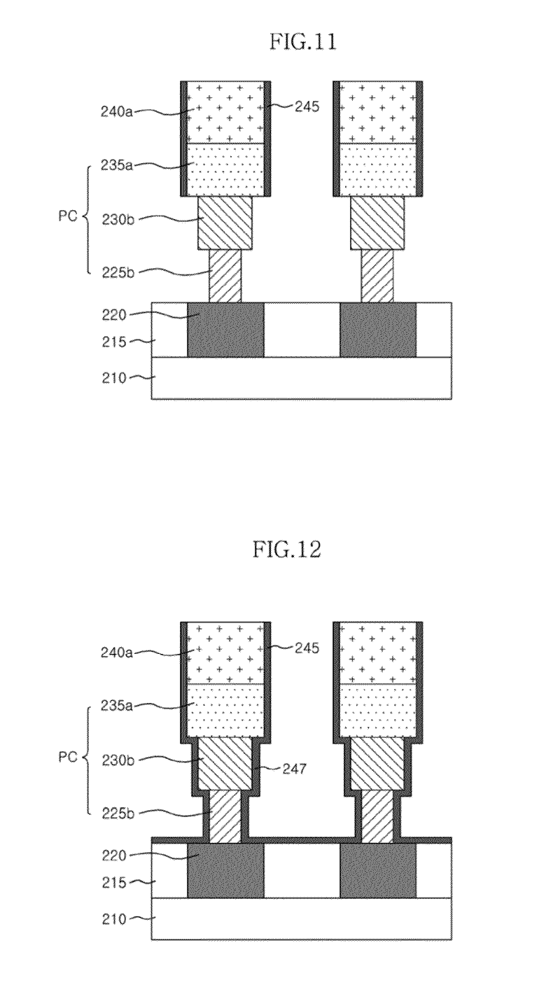

Referring to FIG. 11, the preliminary phase-change structure PPC is subjected to a main etching. The main etching may be performed under specific etching conditions, for instance, as discussed above with respect to FIG. 3. The main etching may be performed so that the exposed second phase-change pattern 230a is etched less than the first phase-change pattern 225a.

Throughout the main etching, a phase-change structure PC having a line width reduced in a stepwise manner is formed. The main etching may be performed using a dry etch method or a wet etch method.

Referring to FIG. 12, a second protection layer 247 may be formed on an exposed phase-change structure PC, that is, surfaces of the second and first phase-change patterns 230b and 225b, a surface of the interlayer insulating layer 215, and a surface of the lower electrode 220.

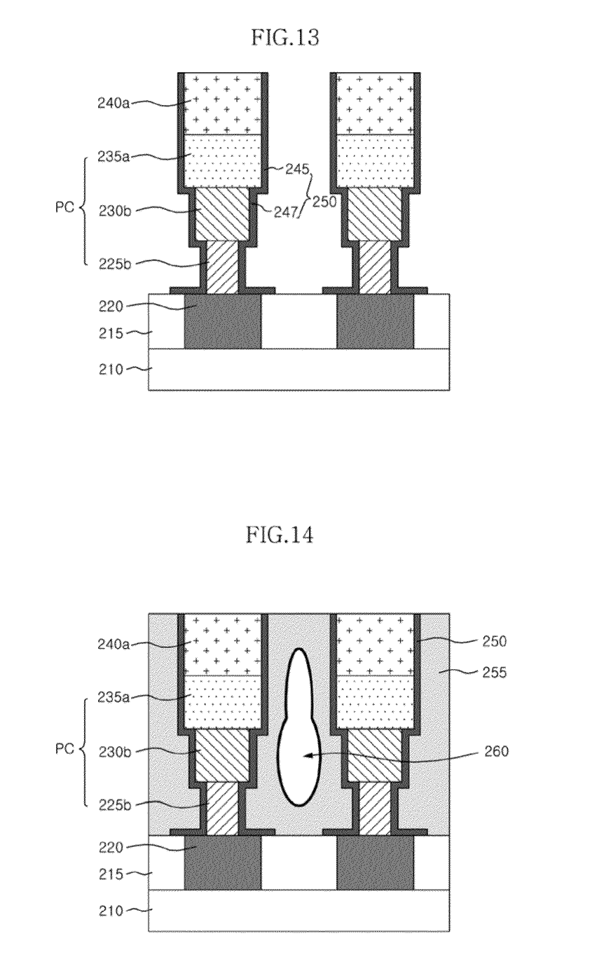

Referring to FIG. 13, a portion of the second protection layer 247 on the interlayer insulating layer 215 may be removed using the first protection layer 245, the upper electrode 240a and the third phase-change pattern 235, as a mask pattern using an anisotropic etching method. In an alternative embodiment, the second protection layer 247, formed on the interlayer insulating layer 215 may remain. Therefore, a side portion of the phase-change structure PC is covered by a protection pattern 250 including the first protection layer 245 and the second protection layer 247.

Referring to FIG. 14, an insulating layer 255 is formed to fill in the space between phase-change structures PC. An air void 260 may be formed in insulating layer 255 due to the aspect ratio of the phase-change structure PC. Since the air void 260 has a high dielectric constant, the air void 260 may serve as an air gap and acts as an insulating layer. Further, the air void 260 may serve as an air gap having low thermal conductivity, and thus the air void 260 may also act as a heat insulating layer. Subsequently, the fill insulating layer 255 is planarized to expose the surface of the upper electrode 240a.

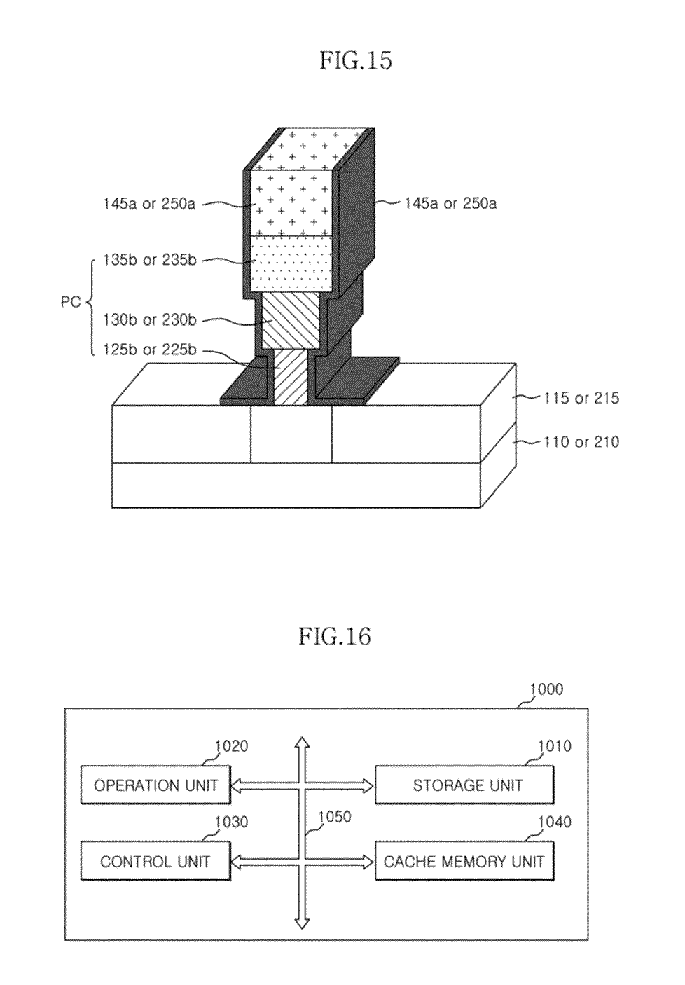

Referring to FIGS. 5, 14, and 15, the first to third phase-change material layers 125, 130, and 135, or 225, 230, and 235 may be sequentially deposited and patterned in a stepwise manner where the line widths of the first to third phase-change material layers 125, 130, and 135, or 225, 230, and 235 are gradually reduced in a direction toward the substrate 110 or 210. Therefore, the phase-change patterns 125b, 130b and 135b or 225b, 230b, and 235b may be formed via a deposition and patterning method, not through a burying method. Thus, a PVD method, which may maintain composition uniformity, may be used to form the phase-change material layers.

In an exemplary embodiment, the phase-change structure PC may have an inverted substantially triangular shape and a space between adjacent phase-change structures PC may have a substantially triangular shape opposite to the shape of the phase-change structure PC. Since the void 155 or 260, which has a low thermal conductivity, is formed in the insulating layer 150 or 255, any thermal disturbance between the phase-change structures PC may be minimized.

Due to the width of the uppermost phase-change material layer 135 or 235, amorphization may not be completely performed in an amorphization operation (that is, a reset operation). A portion of the uppermost phase-change material layer in which the amorphization is not performed serves as a nucleation seed in the following crystallization operation (that is, a set operation). Thus, crystal growth may be performed without a separate time for generation of a nucleation seed, and crystallization speed may be improved.

As illustrated in FIG. 16, a microprocessor 1000, including an exemplary semiconductor device, may control a series of processes that may include receiving data from an external apparatus, processing the data, and transmitting processing results to an external apparatus. The microprocessor 1000 may include a storage unit 1010, an operation unit 1020, or a control unit 1030. The microprocessor 1000 may be a variety of processing apparatuses, such as a central processing unit (CPU), a graphic processing unit (GPU), a digital signal processor (DSP), or an application processor (AP).

The storage unit 1010 may be a processor register or a register, and the storage unit may store data in the microprocessor 1000 and may include a data register, an address register, or a floating point register. The storage unit 1010 may include various registers other than the above-described registers. The storage unit 1010 may temporarily store data to be operated on and processed by the operation unit 1020 The storage unit 1010 may include an exemplary semiconductor device.

The operation unit 1020 may perform an operation in the microprocessor 1000, and may perform an arithmetic operation or a logic operation depending on a decryption result of a command in the control unit 1030. The operation unit 1020 may include one or more arithmetic and logic units (ALUs).

The control unit 1030 may receive a signal from the storage unit 1010, the operation unit 1020, or an external apparatus of the microprocessor 1000, may perform extraction or decryption of a command, may input or output control, or may execute a process in a program form.

The microprocessor 1000 according to the exemplary embodiment may further include a cache memory unit 1040 that may temporarily store data input from an external apparatus or data to be output to an external apparatus, other than the storage unit 1010. The cache memory unit 1040 may exchange data with the storage unit 1010, the operation unit 1020, or the control unit 1030 through a bus interface 1050.

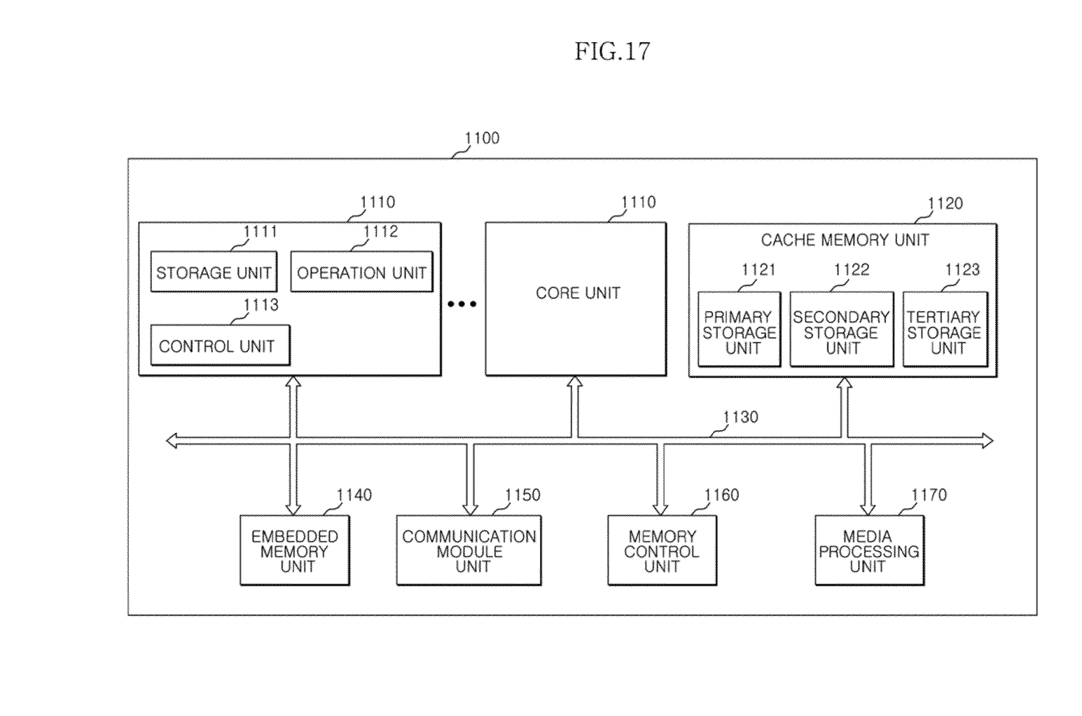

As illustrated in FIG. 17, a processor 1100 may include an exemplary semiconductor device. The processor 1100 may implement various functions to improve the performance and provide additional functionality to the microprocessor 1000. The processor 1100 may include a core unit 1110, a cache memory unit 1120, or a bus interface 1130. The core unit 1110 may perform arithmetic and logic operations on data input from an external apparatus, and may include a storage unit 1111, an operation unit 1112, or a control unit 1113. The processor 1100 may be a variety of system on chips (SoCs), such as a multi core processor (MCP), a graphics processing unit (GPU), or an application processor (AP).

The storage unit 1111 may be a processor register or a register, and the storage unit 1111 may store data in the processor 1100 and may include a data register, an address register, or a floating point register. The storage unit 1111 may include various registers other than the above-described registers. The storage unit 1111 may temporarily store data to be operated on by the operation unit 1112, resulting data processed in the operation unit 1112, or an address where the data to be operated is stored. The operation unit 1112 may perform an operation in the processor 1100, and may perform an arithmetic operation or a logic operation depending on a decryption result of a command in the control unit 1113. The operation unit 1112 may include one or more arithmetic and logic units (ALUs). The control unit 1113 may receive a signal from the storage unit 1111, the operation unit 1112, or an external apparatus of the processor 1100, may perform extraction or decryption of a command, input or output control, or execute a process in a program form.

The cache memory unit 1120 may temporarily store data to supplement a data processing rate of a low speed external apparatus unlike the high speed core unit 1110. The cache memory unit 1120 may include a primary storage unit 1121, a secondary storage unit 1122, and a tertiary storage unit 1123. In general, the cache memory unit 1120 may include the primary and secondary storage units 1121 and 1122. When a high capacity storage unit is necessary, the cache memory unit 1120 may include the tertiary storage unit 1123. If necessary, the cache memory unit 1120 may include more storage units. That is, the number of storage units included in the cache memory unit 1120 may be changed according to design. Here, processing rates of data storage and discrimination of the primary, secondary, and tertiary storage units 1121, 1122, and 1123 may be the same as or different from each other. When the processing rates of the storage units are different, the processing rate of the primary storage unit is the greatest. One or more of the primary storage unit 1121, the secondary storage unit 1122, and the tertiary storage unit 1123 in the cache memory unit 1200 may include an exemplary semiconductor device. The cache memory unit 1120, including the exemplary semiconductor device, may include a phase-change structure having a stacked step structure deposited through a PVD method.

FIG. 17 illustrates that all of the primary, secondary and tertiary storage units 1121, 1122 and 1123 are disposed in the cache memory unit 1120. However, all of the primary, secondary and tertiary storage units 1121, 1122, and 1123 in the cache memory unit 1120 may be disposed outside the core unit 1110, and may supplement a difference between the processing rates of the core unit 1110 and an external apparatus. Further, the primary storage unit 1121 of the cache memory unit 1120 may be located in the core unit 1110, and the secondary storage unit 1122 and the tertiary storage unit 1123 may be located outside the core unit 1110 to further support the function of compensating for processing rates.

The bus interface 1130 may couple the core unit 1110 and the cache memory unit 1120 to efficiently transmit data.

The processor 1100 may include a plurality of core units 1110, and the core units 1110 may share the cache memory unit 1120. The core units 1110 and the cache memory unit 1120 may be coupled through the bus interface 1130. The core units 1110 may have the same configuration as the above-described core unit 1110. When the core units 1110 are provided, the primary storage unit 1121 of the cache memory unit 1120 may be disposed in each of the core units 1110, and one secondary storage unit 1122 and one tertiary storage unit 1123 may be disposed outside the core unit 1110 so that the core units share the secondary and tertiary storage units through the bus interface 1130. The processing rate of the primary storage unit 1121 may be greater than those of the secondary and tertiary storage units 1122 and 1123.

The processor 1100 may further include an embedded memory unit 1140 that may store data, a communication module unit 1150 that may transmit and receive data to and from an external apparatus in a wired manner or a wireless manner, a memory control unit 1160 that may drive an external storage device, and a media processing unit 1170 that may process data in the processor 1100 or data input from an external apparatus and may output a processing result to an external interface device. The processor may further include a plurality of modules other than the above-described components. The additional modules may transmit data to and receive data from the core unit 1110 and the cache memory unit 1120 through the bus interface 1130.

The embedded memory unit 1140 may include volatile memory as well as nonvolatile memory. The volatile memory may include a dynamic random access memory (DRAM), a mobile DRAM, a static RAM (SRAM), or the like, and the nonvolatile memory may include a read only memory (ROM), a NOR flash memory, a NAND flash memory, a phase-change RAM (PCRAM), a resistive RAM (RRAM), a spin transfer torque RAM (STTRAM), a magnetic RAM (MRAM), or the like. The exemplary semiconductor device may also be applied to the embedded memory unit 1140.

The communication module unit 1150 may include a module coupled to a wired network or a module coupled to a wireless network. The wired network module may include a local area network (LAN), a universal serial bus (USB), Ethernet, power line communication (PLC), or the like. The wireless network module may include Infrared Data Association (IrDA), Code Division Multiple Access (CDMA), Time Division Multiple Access (TDMA), Frequency Division Multiple Access (FDMA), a wireless LAN, Zigbee, a Ubiquitous Sensor Network (USN), Bluetooth, Radio Frequency Identification (RFID), Long Term Evolution (LTE), Near Field Communication (NFC), Wireless Broadband Internet (Wibro), High Speed Downlink Packet Access (HSDPA), Wideband CDMA (WCDMA), Ultra WideBand (UWB), or the like.

The memory control unit 1160 may manage data transmitted between the processor 1100 and an external apparatus that may operate according to a different communication standard from the processor 1100. The memory control unit 1160 may include a variety of memory controllers, or a controller that may control Integrated Device Electronics (IDE), Serial Advanced Technology Attachment (SATA), a Small Computer System Interface (SCSI), a Redundant Array of Independent Disks (RAID), a solid state disk (SSD), External SATA (eSATA), Personal Computer Memory Card International Association (PCMCIA), a USB, a secure digital (SD) card, a mini secure digital (mSD) card, a micro SD card, a secure digital high capacity (SDHC) card, a memory stick card, a smart media (SM) card, a multimedia card (MMC), an embedded MMC (eMMC) a compact flash (CF) card, or the like.

The media processing unit 1170 may process data in the processor 1100 or data input from an external input device, and may output a processing result to an external interface device so that the processing result may be transferred in video, sound, or other mediums. The media processing unit 1170 may include a GPU, a DSP, a HD audio, a high definition multimedia interface (HDMI) controller, or the like.

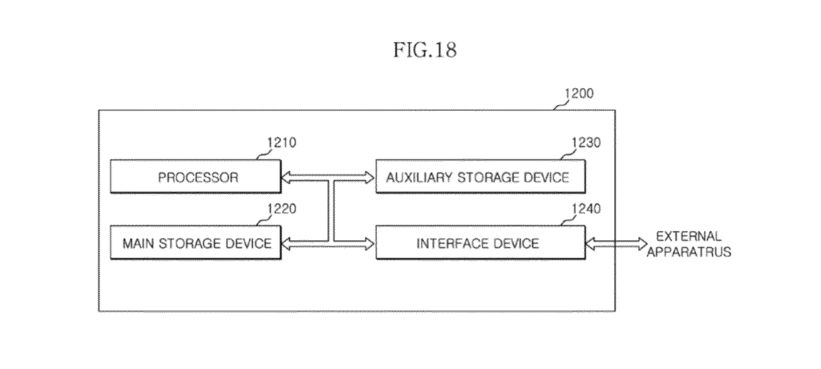

As illustrated in FIG. 18, the system 1200 where the exemplary semiconductor device may be applied is a data processing apparatus. The system 1200 may perform input, processing, output, communication, storage, and the like in a series of operations on data, and may include a processor 1210, a main storage device 1220, an auxiliary storage device 1230, or an interface device 1240. The system according to the embodiment may operate using a processor, such as a computer, a server, a personal digital assistant (PDA), a portable computer, a web tablet, a wireless phone, a mobile phone, a smart phone, a digital music player, a portable multimedia player (PMP), a camera, a global positioning system (GPS) a video camera, a voice recorder, Telematics, an audio visual (AV) system, or a smart television.

The processor 1210 may control processing of data stored in the system, and may include a MPU, a CPU, a single/multi core processor, a GPU, an AP, a DSP, or the like.

The main storage unit 1220 may receive a program or data from the auxiliary storage device 1230 and execute the program or the data when the program is executed. The main storage device 1220 may retain the stored content even when powered off, and may include the exemplary semiconductor.

The main storage device 1220 may further include an SRAM or a DRAM volatile memory, in which all contents are erased when power is off. Alternatively, the main storage device 1220 may not include the exemplary semiconductor device, but may include an SRAM or a DRAM volatile memory.

The auxiliary storage device 1230 may store a program code or data. The auxiliary storage device 1230 may have a lower data processing rate than the main storage device 1220, but may store large amounts of data and may include the exemplary semiconductor device.

An area of the auxiliary storage device 1230 may be reduced to decrease the system 1200 size and increase portability. Further, the auxiliary storage device 1230 may include a data storage system (not shown), such as a magnetic tape or a magnetic disc, a laser disc, a magneto-optical disc, an SSD, a USB memory, a SD card, a mSD card, a micro SD card, a SDHC card, a memory stick card, a SM card, a MMC, an eMMC, or a CF card. Alternatively, the auxiliary storage device 1230 may not include the exemplary semiconductor device, but may include a data storage system (not shown), such as a magnetic tape or a magnetic disc, a laser disc, a magneto-optical disc, an SSD, a USB memory, a SD card, a mSD card, a micro SD card, a SDHC card, a memory stick card, a SM card, a MMC, an eMMC, or a CF card.

The interface device 1240 may exchange a command and data of an external apparatus with the system of the exemplary embodiment, and may be a keypad, a keyboard, a mouse a speaker, a microphone, a display, a variety of Human Interface Devices (HIDs), or a communication device. The communication device may include a module coupled to red network or a module coupled to a wireless network. The wired network module may include a LAN, a USB, Ethernet, PLC, or the like, and the wireless network module may include IrDA, CDMA, TDMA, FDMA, a wireless LAN, Zigbee, a USN, Bluetooth, RFID, LTE, NFC, Wibro, HSDPA, WCDMA, UWB, or the like.

The above exemplary embodiments of the present invention are illustrative and not limiting. Various alternatives and equivalents are possible. The invention is not limited by the exemplary embodiment described herein, nor is the invention limited to any specific type of semiconductor device. Other additions, subtractions, or modifications are obvious in view of the present disclosure and are intended to fall within the scope of the appended claims.

What is claimed is:

1. A method of manufacturing a semiconductor integrated circuit device comprising:
providing a semiconductor substrate including a lower electrode;
sequentially stacking a plurality of phase-change material layers on the semiconductor substrate; and
patterning the stacked plurality of phase-change material layers in a stepwise manner to form a phase-change structure.

2. The method of claim 1, wherein each phase-change material layer, of the plurality of stacked phase-change material layers, is formed via a physical vapor deposition (PVD) method.

3. The method of claim 2, wherein an etch rate of each phase-change material layer, of the stacked plurality of phase-change material layers, reduced in a direction extending away from the substrate under a specific etch condition.

4. The method of claim 2, wherein an etch rate of each phase-change material layer, of the stacked plurality of phase-change material layers, is reduced in a direction extending toward the substrate under a specific etch condition.

5. The method of claim 1, further comprising:
forming an upper electrode layer on the plurality of phase-change material layers, and
patterning the upper electrode layer.

6. The method of claim 5, wherein the patterning the stacked phase-change material layers includes:
forming a preliminary phase-change structure by etching the upper electrode layer and the plurality of phase-change material layers; and
forming the phase-change structure by etching the preliminary phase-change structure so that a width of each phase-change material layer, of the stacked plurality of phase-change material layers, is reduced in a direction extending toward the substrate.

7. The method of claim 6 wherein the etching the upper electrode layer and the stacked plurality of phase-change material layers further comprises:
etching the upper electrode and the stacked plurality of phase-change material layers at a substantially the same etch rate.

8. The method of claim 6, wherein the etching the preliminary phase-change structure further comprises:
etching a phase-change material layer, of the stacked plurality of phase-change material layers, that is closer to the substrate at a faster etch rate than a phase-change material layer of the stacked plurality of phase-change material layers, that is further away from the substrate.

9. The method of claim 5, wherein the patterning the stacked phase-change material layers includes:
etching the upper electrode layer and an uppermost phase-change material layer, of the stacked plurality of phase-change material layers;
forming a preliminary phase-change structure by etching remaining phase-change material layers, of the stacked plurality of phase-change material layers; and forming the phase-change structure by etching the preliminary phase-change structure so that a width of each phase-change material layer, of the stacked plurality of phase-change material layers, is reduced in a direction extending toward the substrate.

10. The method of claim 9, wherein etching the remaining phase-change material layers, of the stacked plurality of phase-change material layers further comprises:
performing an anisotropic etching.

11. The method of claim 5, wherein the patterning the stacked phase-change material layers includes:
forming a preliminary phase-change structure by etching the upper electrode layer and the plurality of phase-change material layers; and
forming the phase-change structure by etching the preliminary phase-change structure so that a width of each phase-change material layer, of the stacked plurality of phase-change material layers, is reduced in a direction extending away from the substrate.

12. The method of claim 1, further comprising:
forming a protection layer over a sidewall of the phase-change structure; and
forming an insulating layer in a space between the phase-change structure and an adjacent phase-change structure.

13. A method of manufacturing a semiconductor integrated circuit device, the method comprising:
providing a semiconductor substrate including a lower electrode;
sequentially stacking a plurality of phase-change material layers, each having a different material property, on the semiconductor substrate via a physical vapor deposition (PVD) method; and
patterning the stacked plurality of phase-change material layers based on the different material properties to form a phase-change structure.

14. The method of claim 13, wherein the plurality of phase-change material layers further comprises:
patterning the stacked plurality of phase-change material layers so that a width of the phase-change structure increases in a direction extending away from the substrate.

15. The method of claim 13, wherein the plurality of phase-change material layers further comprises:
patterning the stacked plurality of phase-change material layers so that a width of the phase-change structure decreases in a direction extending away from the substrate.

16. The method of claim 13, further comprising:
forming an insulating layer in a space between the phase-change structure and an adjacent phase-change structure.

17. The method of claim 16, further comprising:
forming a protection layer on a side of the phase-change structure; and
forming the insulating layer on the protection layer.

18. The method of claim 1, wherein each phase-change material layer, of the plurality of stacked phase-change material layers, has a different etch selectivity.

19. The method of claim 6, wherein the upper electrode and an uppermost phase-change material layer, of the stacked plurality of phase-change material layers, have substantially the same width.

20. The method of claim 9 wherein etching the upper electrode layer and an uppermost phase-change material layer further comprises:
etching the upper electrode layer and the uppermost phase-change material layer at a substantially the same rate.
